(19) United States
(12) Patent Application Publication
(10) Pub. No.: US 2010/0302745 A1
(43) Pub. Date: Dec. 2, 2010

(54) LEAD FRAME WITH STITCHING-ASSISTING STRUCTURES, ELECTRONIC DEVICE HAVING SUCH LEAD FRAME AND APPARATUS HAVING SUCH ELECTRONIC DEVICE

(75) Inventors: FU-BIAU HSU, Taipei City (TW); CHUN-JUNG KUO, Taipei City (TW)

Correspondence Address: COVENANT IP CONSULTING CO., P.O. BOX 34-306 TAIPEI CITY, TAIPEI, 10499, TW

(73) Assignee: FU-BIAU HSU, Taipei City (TW)

(21) Appl. No.: 12/787,376

(22) Filed: May 25, 2010

(30) Foreign Application Priority Data
May 26, 2009 (TW) 098209184

(51) Int. Cl. H05K 1/00; H05K 7/18

(52) U.S. Cl. 361/749; 361/813

(57) ABSTRACT

The invention discloses a lead frame having stitching-assisting structures, an electronic device having such lead frame, and an apparatus having such electronic device. The apparatus according to the invention also includes a flexible substrate and a plurality of conductive threads. Particularly, the conductive threads are sewn through the flexible substrate and the stitching-assisting structures to fix the electronic device on the flexible substrate, and the conductive threads electrically contact with the stitching-assisting structures of the electronic device.

### BACKGROUND OF THE INVENTION

1. Field of the Invention

This present invention relates to a lead frame having stitching-assisting structures, an electronic device having such lead frame, and an apparatus having such electronic device.

2. Description of the Prior Art

Applications for electronic circuits gradually involve in connecting electronic circuits to conductors and electronic devices in textile articles to make textile articles (e.g., generally available fabrics and clothing) able to integrate with the electronic circuits for various functionalities. One of the aforesaid applications includes wearable electronic circuits which are fixed on or embedded into fabric or clothing. These wearable electronic circuits can be connected to conductive threads fabricated into the fabric or clothing, and thereby, these electronic circuits and components (e.g., switches or other input/output devices) can function in the textile articles.

One of obstacles to practical application of such wearable electronic circuits is connecting way in which the electronic components are connected to conductive threads fabricated into the fabric or clothing. Conductive threads are successfully served as wearable wires, but it is very difficult to bond these conductive threads on electronic devices in an efficient and cost effective manner and to achieve enough strength on the bonding point to withstand being worn and washed during using. Approaches involving in use of solder and/or printed circuit boards are significantly complicate, cost too much, and cannot be integrated with traditional textile process.

U.S. Pat. No. 7,025,596 discloses a method and apparatus to form electric connections in a solder-less way between electronic circuits (such as semiconductor dies) and conductive threads that are interwoven into textile material. According to the prior art, the electronic circuits are fixed on a carrier and electrically connected, for example in a wire bonding way or a soldering way, to conductive traces on the carrier that can be sewn through. The conductive threads are inter-sewn on each of the conductive traces to electrically contact with the conductive trace, and also sewn to the conductive threads on the textile material corresponding to the conductive trace. The carrier is further fixed on the textile material for example in sewing way.

However, the prior art need to use the carrier, capable of being sewn through, which inherently has to be finished in design and manufacture of traditional electronic circuits. As a result, the prior art significantly limits availability of electronic devices, especially only utilizes traditional electronic devices having traditional pins. In addition, it is doubt that the connection between the carrier and textile material and the electrical contact between the conductive threads and the conductive trace are strong enough to withstand being long-term worn and frequently washed. Moreover, the assembling of electronic circuits and the carrier and the connecting procedures of the textile material are too much complicated.

### SUMMARY OF THE INVENTION

Accordingly, one aspect of the invention is to provide a lead frame having pins, and in particular, the pins of the lead frame have stitching-assisting structures.

In addition, another aspect of the invention is to provide an electronic device having the lead frame according to the invention and an apparatus having such electronic device. The apparatus according to the invention also includes a flexible substrate and a plurality of conductive threads. In particular, the conductive threads are sewn through the flexible substrate and the stitching-assisting structures to fix the electronic device on the flexible substrate. The conductive threads electrically contact with the stitching-assisting structures of the electronic device. Thereby, the sewing and fixing electronic device is strong enough to withstand being long-term worn and frequently washed. More importantly, the electronic device according to the invention can be fixed in textile way.

According to the first preferred embodiment of the invention, the lead frame includes a base and at least two pins protruding from the base. Particularly, each of the pins has at least one stitching-assisting structure such as through holes or openings.

According to the second preferred embodiment of the invention, the electronic device includes a circuit component and a lead frame. The circuit component is packaged with the lead frame. The lead frame includes a base and at least two pins extended from the base. Particularly, each of the pins has at least one stitching-assisting structure such as through holes or openings.

According to the third preferred embodiment of the invention, the apparatus includes a flexible substrate, an electronic device and a plurality of conductive threads. The flexible substrate is capable of being sewn through by stitching. The electronic device includes a circuit component and a lead frame with which the circuit component is packed. The lead frame includes a base and at least two pins protruding from the base. In particular, each of the pins has at least one stitching-assisting structure such as through holes or openings. The conductive threads are sewn through the flexible substrate, and pass through and are interwoven between the stitching-assisting structures to fix the electronic device on the flexible substrate, where the conductive threads electrically contact with the stitching-assisting structures.

The aspect of the present invention will no doubt become obvious to those of ordinary skill in the art after reading the following detailed description of the preferred embodiment, which is illustrated in the following figures and drawings.

### BRIEF DESCRIPTION OF THE APPENDED DRAWINGS

FIG. 1A illustratively shows the lead frame 10 according to the first preferred embodiment of the invention where the pins 104 of the lead frame 10 have the stitching-assisting structures 106a in form of through holes.

FIG. 1B illustratively shows the modification of the lead frame 10 according to the first preferred embodiment of the invention where the pins 104 of the lead frame 10 has the stitching-assisting structures 106b in form of openings.

FIG. 2A illustratively shows the electronic device 20 according to the second preferred embodiment of the invention where the electronic device 20 is packaged by use of the lead frame 10 shown in FIG. 1A.

FIG. 2B illustratively shows the modification of the electronic device 20 according to the second preferred embodiment of the invention where the electronic device 20 is packaged by use of the lead frame 10 shown in FIG. 1B.

FIG. 2C illustratively shows the modification of the electronic device 20 according to the second preferred embodiment of the invention where the electronic device 20 has the dummy pins 104′.

FIG. 3 illustratively shows an apparatus 30 according to the third preferred embodiment of the invention where the apparatus 30 includes the electronic device 20 as shown in FIG. 2A.

### DETAILED DESCRIPTION OF THE INVENTION

Some preferred embodiments and practical applications of this present invention would be explained in the following paragraph, describing the characteristics, spirit and advantages of the invention.

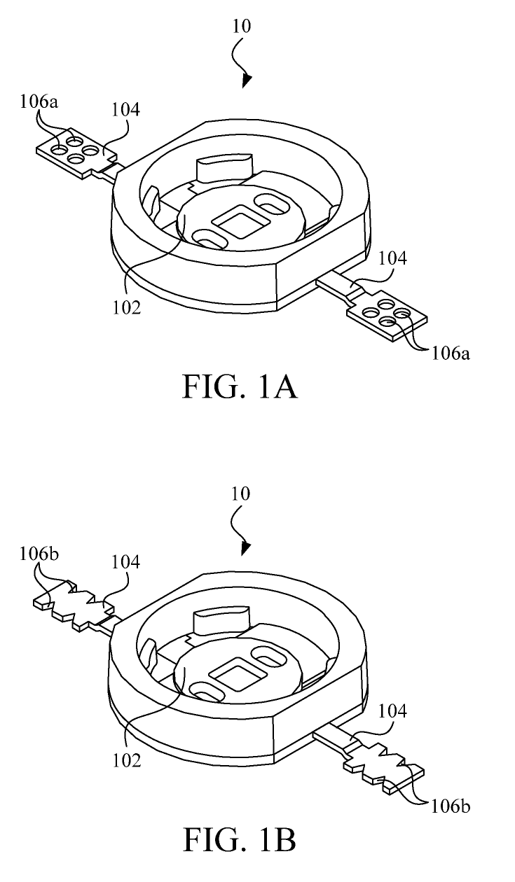

Referring to FIGS. 1A and 1B, those figures disclose a lead frame 10 according to the first preferred embodiment of the invention.

As shown in FIG. 1A and FIG. 1B, the lead frame 10 according to the first preferred embodiment of the invention includes a base 102 and at least two pins 104. FIG. 1A and FIG. 1B illustratively show a lead frame for package of a semiconductor light-emitting device. Therefore, only two pins 104 are drawn in those figures for explanation.

Also as shown in FIG. 1A and FIG. 1B, the two pins 104 protrude from the base 102. Particularly, each of the pins 104 has at least one stitching-assisting structure (106a and 106b), such as four through holes 106a shown in FIG. 1A or six openings 106b shown in FIG. 1B. It needs to be stressed that the stitching-assisting structures of the pins disclosed in the invention are not limited to through holes and openings.

For conductive and robust purpose, the base 102 and the pins 104 are mostly made of a metal material. In addition, in order to isolate different electrodes of the lead frame 10 and to fix the base 102 and the pins 104, just like general lead frames, the space between the base 102 and the pins 104a is formed into a seat of a polymer material, as shown in FIG. 1A and FIG. 1B. Obviously, the lead frame according to the present invention is easy to manufacture.

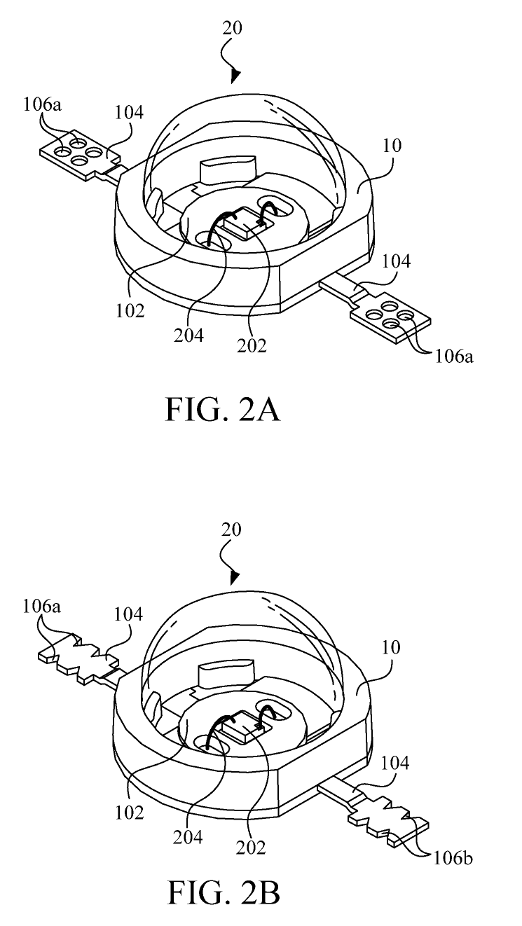

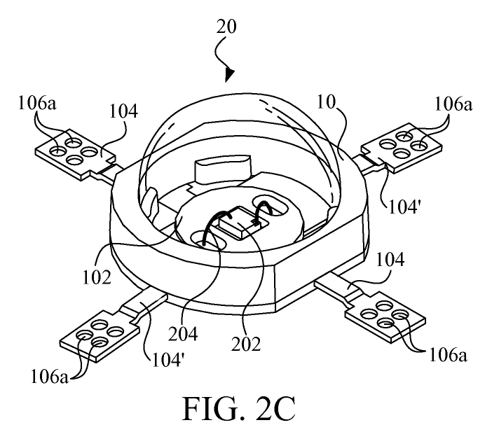

Referring to FIGS. 2A, 2B, and 2C, those figures disclose an electronic device 20 according to the second preferred embodiment of the invention.

As shown in FIGS. 2A and 2B, the electronic device 20 according to the second preferred embodiment of the invention includes a lead frame 10 and a circuit component 202, such as a semiconductor light emitting device, an integrated circuit, a photo-detector, a solar cell, a power supply, a micro-electromechanical functional device, a switch, a memory, a processor, a passive component, etc. The circuit component 202 is packaged with the lead frame 10.

Similar to FIGS. 1A and 1B, the lead frame 10 shown in FIGS. 2A and 2B is provided for package of a semiconductor light-emitting device, and therefore, only two pins 104 are drawn in FIGS. 2A and 2B for explanation. Similarly, the circuit component 202 as shown in FIGS. 2A and 2B is a semiconductor light-emitting device for explanation.

The circuit component 202 is packaged with the lead frame 10. As the case disclosed in FIGS. 2A and 2B, the circuit component (semiconductor light-emitting device) 202 is fixed on the base 102, and the electrodes thereon are electrically connected with metal wires 204 to the corresponding electrodes of the lead frame 10 in a wire bonding way. Similarly, as the case disclosed in FIGS. 2A and 2B, the space between the base 102 and the pins 104 is formed into a seat of a polymer material with a cavity, and the and the cavity of the seat is filled with transparent material, such as epoxy or glass, to seal the circuit component (semiconductor light-emitting device) 202, and to provide optical design.

Also shown in FIGS. 2A and 2B, the pins 104 protrude from the base 102. Particularly, each of the pins 104 has at least one stitching-assisting structure (106a, 106b), such as the four through holes 106a as shown in FIG. 1A or the six openings 106b as shown in FIG. 1B. It needs to be stressed that the stitching-assisting structures of the pins disclosed in the invention are not limited to through holes and openings.

Obviously, the electronic device 20 can be sewn firmly with conductive threads by a sewing machine or in hand-made sewing to be fixed on a flexible substrate. By the conductive threads, the electronic device 20 directly electrically contacts the conductive area on the flexible substrate, provides the electric connection with another electronic circuit or a power source. Moreover, the sewn and fixed electronic device 20 is strong enough to withstand being long-term worn and frequently washed. In addition, the electronic device according to the invention can be widely applied in current electronic devices with pins.

Further, in order to sew the electronic device 20 more firmly on the flexible substrate to make the sewn electronic device 20 able to withstand being long-term worn and frequently washed, the electronic device 20 shown in FIG. 2C, substantially similar to the electronic device 20 shown in FIG. 2A, further has at least one dummy pin 104′ without electric connection function. Particularly, each of the dummy pins 104′ has at least one stitching-assisting structure 106a, such as four through holes 106a as shown in FIG. 2C. The construction and component in FIG. 2C that are marked with the same numbers as in FIG. 2A, relatively function respectively as those in FIG. 2A, and it will not be described in detail again.

By the stitching-assisting structures 106a, the pins 104 of the electronic device 20 shown in FIG. 2C can be sewn firmly by conductive threads to be fixed on a flexible substrate, and provide with electrical connection. And particularly, the dummy pins 104′ of the electronic device 20 shown in FIG. 2C can be sewn firmly by conductive threads or non-conductive threads to be fixed on the flexible substrate.

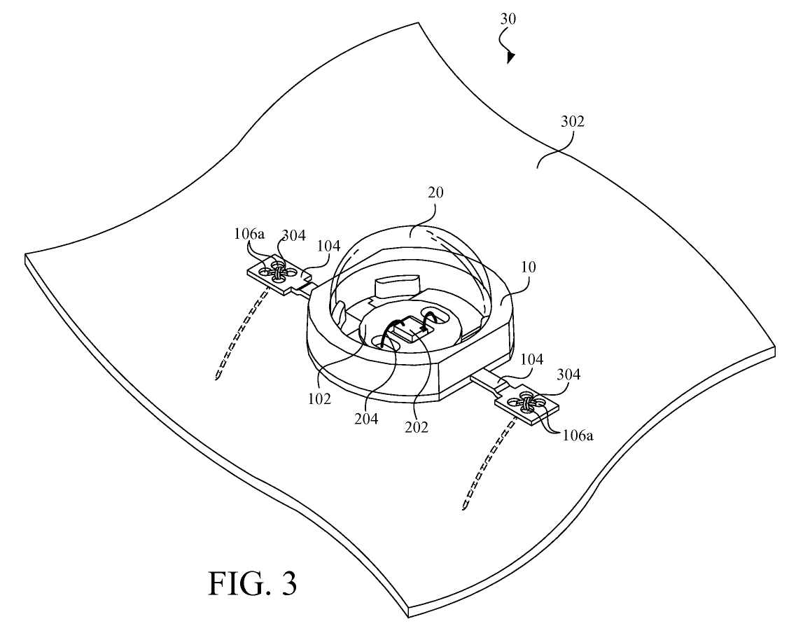

Referring to FIG. 3, FIG. 3 discloses an apparatus 30 according to the third preferred embodiment of the invention.

As shown in FIG. 3, the apparatus 30 according to the third preferred embodiment of the invention includes a flexible substrate 302, a plurality of conductive threads 304 and an electronic device 20, such as a light emitting-diode, a laser diode, a photo-detector, an integrated circuit, a solar cell, a power supply, a switch, a memory, a micro-electromechanical functional device, a processor, a passive components, etc.

Similar to FIG. 2A, the electronic device 20 shown in FIG. 3 is drawn as a light-emitting diode with two pins 104 for explanation.

Also shown in FIG. 3, the flexible substrate 302 is capable of being sewn through. The electronic device 20 includes a lead frame 10 and a circuit component 202 (such as a semiconductor light-emitting device), and the circuit component 202 is packaged with the lead frame 10. As the case disclosed in FIG. 3, the circuit component (semiconductor light-emitting device) 202 is fixed on the base 102, and the electrodes thereof are respectively electrically connected with metal wires 204 to the corresponding electrodes on the lead frame 10 in a wire bonding way. Similarly, as the case disclosed in FIG. 3, the space between the base 102 and the pins 104 is formed into a seat of a polymer material with a cavity, and the and the cavity of the seat is filled with transparent material, such as epoxy or glass, to seal the circuit component (semiconductor light-emitting device) 202, and to provide optical design.

Also shown in FIG. 3, the pins 104 protrude from the base 102. Each of the pins 104 has at least one stitching-assisting structure 106a, such as the four through holes 106a shown in FIG. 2C or the six openings 106b shown in FIG. 2B. It needs to be stressed that the stitching-assisting structures formed on the pins disclosed in the invention are not limited to the through holes and the openings. The conductive threads 304 can sew through the flexible substrate 302 by a sewing machine or in hand-made sewing, and pass through the stitching-assisting structures 106a to firmly fix the electronic device 20 on the flexible substrate 302. Particularly, the conductive threads 304 electrically contact with the stitching-assisting structures (106a, 106b), and the conductive threads 304 provide the electronic device 20 with electrical connection for another electronic circuit on the flexible substrate 302. Obviously, the electronic device 20 sewn by the conductive threads 304 is strong enough to withstand being long-term worn and frequently washed. Obviously, the electronic device 20 can be sewn firmly by conductive threads to be fixed on the flexible substrate 302, and directly electrically contacts the conductive area of the flexible substrate 302 by the conductive threads or are electrically connected to another electronic circuit or a power source. Moreover, the sewn and fixed electronic device 20 is strong enough to withstand being long-term worn and frequently washed.

In practical application, the conductive threads 304 are also sewn on the flexible substrate 302 to form an electrical connection circuit for another electronic circuit or a power source.

In one embodiment, the flexible substrate 302 is a textile article or an article of a polymer.

In one embodiment, one of the conductive threads 304 can be a metal line constituted by at least one metal wire. One of the conductive threads 304 can also be a coupling yarns constituted by at least one conductive core filament, a plurality of conductive short fibers, at least one non-conductive core filament or a plurality of non-conductive short fibers coupling with at least one metal wire. One of the conductive threads 304 can also be another coupling yarn constituted by at least one conductive core filament, a plurality of conductive short fibers, at least one non-conductive core filament or a plurality of non-conductive short fibers coupling with at least one rolled metal wire. One of the conductive threads 304 can also be a twisted yarn constituted by at least one metal wire twisting with at least one non-conductive yarn or one metal wire. One of the conductive threads 304 can also be a doubled yarn constituted by at least one metal wire paralleling with at least one metal wire or one non-conductive yarn without any twist. One of the conductive threads 304 can also be a twisted yarn constituted by combination of aforesaid metal wires, coupling yarns, doubled yarns and twisted yarns. The constituents of aforesaid conductive threads 304 can be suitably selected to meet requirement of specific functions, e.g., tensile strength, flexibility, fire resistance, conductivity, etc.

In one embodiment, materials used to fabricate aforesaid metal wires and rolled metal wires can be tin plating copper, gold plating copper, nickel plating copper, copper, CuNi alloys, CuNiSi alloys, CuNiZn alloys, CuNiSn alloys, CuCr alloys, CuAg alloys, CuW alloys, silver, gold, lead, zinc, aluminum, nickel, brass, phosphor bronze, beryllium copper, nichrome, tantalum, tungsten, platinum, palladium, stainless steels (e.g., 316, 304, 420, stainless steel containing Cu or Ag), titanium, titanium alloys (e.g., TA0, TA1, TA2, TA3, TA7, TA9, TA10, TC1, TC2, TC3, TC4(Ti6Al4V)), Ni—Cr—Mo—W alloy, zirconium, zirconium alloys (e.g., alloy 702, alloy 704, alloy 705, alloy 706), HASTELLOY alloys (e.g., alloy C-22, alloy B-2, alloy C-22), Nickel alloys (e.g., Nickel 200, Nickel 201), MONEL alloys (e.g., alloy 400, alloy R-405, alloy K-500), ICONEL alloys (e.g., alloy 600, alloy 625), FERRALIUM alloy (alloy 255), NITRONIC alloys (e.g., NITRONIC 60, NITRONIC 50, NITRONIC 30), CARPENTER alloy (alloy 20Cb-3), or other commercial metals or alloys.

To sum up, compared with the prior arts of connecting electronic devices to flexible substrates such as textile articles, the apparatus incorporating with the electronic device according to the invention has the sewn and fixed the electronic device strong enough to withstand being long-term worn and frequently washed, and utilizes the electronic device in wide variety. According to the invention, the connection between the electronic device and the flexible substrate is achieved by sewing with conductive threads. Obviously, the present invention can be easily carried out by a textile process without the pollution of soldering process. In addition, according to the invention, it is easy to fabricate the lead frame, and to sew the conductive threads on the flexible substrate to form an electrical connection circuit for another electronic circuit or a power source. Obviously, the invention has the advantages and effects that the prior art cannot achieve.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A lead frame, comprising:
a base; and
at least two pins protruding from the base, each of the pins having at least one stitching-assisting structure.

2. The lead frame of claim 1, within each of the stitching-assisting structures is a through hole or an opening.

3. An electronic device, comprising
a circuit component; and
a lead frame, with which the circuit component is packaged, the lead frame comprising:
a base; and
at least two pins protruding from the base, each of the pins having at least one stitching-assisting structure.

4. The electronic device of claim 3, wherein one of the stitching-assisting structures is a through hole or an opening.

5. An apparatus, comprising:
a flexible substrate capable of being sewn through by stitching;
an electronic device, comprising:
a circuit component; and
a lead frame with which the circuit component is packaged, the lead frame comprising:
a base; and
at least two pins protruding from the base, each of the pins having at least one stitching-assisting structure; and
a plurality of conductive threads being sewn through the flexible substrate and passing through and being interwoven between the stitching-assisting structures to fix the electronic device on the flexible substrate, wherein the conductive threads electrically contact with the stitching-assisting structures.

6. The apparatus of claim 5, wherein one of the stitching-assisting structures is a through hole or an opening.

7. The apparatus of claim 5, wherein the conductive threads are also sewn on the flexible substrate to form an electric connection.

8. The apparatus of claim 5, wherein the flexible substrate is a textile article or a polymer article.

9. The apparatus of claim 5, within the conductive threads comprise one selected from the group consisting of a first metal line, a first coupling yarn, a second coupling yarn, a first twisted yarn, a doubled yarn, and a second twisted yarn constituted by combinations thereof, said first metal line is constituted by at least one metal wire, said first coupling yarn is constituted by at least one conductive core filament, a plurality of conductive short fibers, at least one non-conductive core filament or a plurality of non-conductive short fibers coupling with at least one metal wire, said second coupling yarn is constituted by at least one conductive core filament, a plurality of conductive short fibers, at least one non-conductive core filament or a plurality of non-conductive short fibers coupling with one or a plurality of rolled metal wires, said first twisted yarn is constituted by at least one metal wire twisting with at least one non-conductive yarn or one metal wire, said doubled yarn is constituted by at least one metal wire paralleling with at least one metal wire or one non-conductive yarn without any twist, said second twisted yarn is constituted by the first metal line, the first coupling yarn, the second coupling yarn, the doubled yarn, and the first twisted yarn.

10. The apparatus of claim 9, within the metal wire and the rolled metal wire are made of a material selected from the group consisting of tin plating copper, gold plating copper, nickel plating copper, copper, CuNi alloys, CuNiSi alloys, CuNiZn alloys, CuNiSn alloys, CuCr alloys, CuAg alloys, CuW alloys, silver, gold, lead, zinc, aluminum, nickel, brass, phosphor bronze, beryllium copper, nichrome, tantalum, tungsten, platinum, palladium, stainless steels, titanium, titanium alloys, Ni—Cr—Mo—W alloy, zirconium, zirconium alloys, HASTELLOY alloys, Nickel alloys, MONEL alloys, ICONEL alloys, FERRALIUM alloy, NITRONIC alloys, and CARPENTER alloy.
